(19) United States
(12) Patent Application Publication
(10) Pub. No.: US 2009/0166067 A1
(43) Pub. Date: Jul. 2, 2009

(54) CLAD MEMBER AND PRINTED-CIRCUIT BOARD

(75) Inventors: Ichiro Iwai, Tochigi (JP); Kazuo Kimura, Tochigi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: SHOWA DENKO K.K., Minato-ku (JP)

(21) Appl. No.: 11/912,995

(22) PCT Filed: Apr. 28, 2006
(86) PCT No.: PCT/JP2006/309363

§ 371 Date: Jan. 23, 2009

Related U.S. Application Data
(60) Provisional application No. 60/679,667, filed on May 11, 2005.

(30) Foreign Application Priority Data
Apr. 28, 2005 (JP) 2005-132493

(51) Int. Cl. H05K 1/09; B32B 15/01; B23K 20/04

(52) U.S. Cl. 174/257; 428/654; 228/117

(57) ABSTRACT

A clad member low in thermal expansion coefficient and excellent in workability is provided. The clad member 1 comprises a core member 11 and skin members 12 cladded on both sides of the core member. The core member 11 is constituted by an aluminum alloy consisting of Si: 5 to 30 mass %, and the balance being aluminum alloy and impurities. The skin member 12 is constituted by aluminum or an aluminum alloy consisting of Al: 98 mass % or above, and the balance being impurities.

### CROSS REFERENCE TO RELATED APPLICATIONS

This application is an application filed under 35 U.S.C.§111(a) claiming the benefit pursuant to 35 U.S.C.§119(e)(1) of the filing date of U.S. Provisional Application No. 60/679,667 filed on May 11, 2005, pursuant to 35 U.S.C.§111(b).

This application claims priority to Japanese Patent Application No. 2005-132493 filed on Apr. 28, 2005, and U.S. Provisional Application No. 60/679,667 filed on May 11, 2005, the entire disclosures of which are incorporated herein by reference in their entireties.

### TECHNICAL FIELD

The present invention relates to a clad member, especially to a clad member excellent in workability, a production method of the clad member, and a printed-circuit board using the clad member as a substrate.

### BACKGROUND ART

The following description sets forth the inventor's knowledge of related art and problems therein and should not be construed as an admission of knowledge in the prior art.

As shown in FIG. 1, a printed-circuit board 1 includes an aluminum substrate 2, an insulating layer 3 laminated on the aluminum substrate, a conducting layer 4 of a prescribed shape laminated on the insulating layer 3. On the conducting layer 4, an electronic component 5 is bonded with solder 6. Generally, in such a printed-circuit board 1, pure aluminum of JIS 1xxx series excellent in heat conductance is used as the material of the substrate 2, and a copper foil is used as the conducting layer 4.

As shown in Table 1, however, since the copper foil 4 and the aluminum substrate 2 are different in thermal expansion coefficient, i.e., the thermal expansion coefficient of the copper foil 4 is about 17×10⁻⁶/K and that of the aluminum substrate 2 is about 24×10⁻⁶/K, the repetition of heating and cooling thereof by energization repeatedly causes warpings of the printed-circuit board 1 in the opposite directions due to the difference of the thermal expansion coefficient. Furthermore, since the thermal expansion coefficient of the electronic component 5 is 2×10⁻⁶ to 8×10⁻⁶/K, which is different from that of the copper 4 and that of the aluminum substrate 2, the repetition of the warping of the printed-circuit board 1 causes cracks in the solder 6 due to the stress.

To solve such a problem, there is a proposal that a rolled sheet made of an Al—Si series alloy lower than JIS 1xxx series aluminum in thermal expansion coefficient is used as an aluminum substrate 2 (see, Japanese Unexamined Laid-open Patent Publication No. H06-41667 (hereinafter, Patent Document 1), Japanese Unexamined Laid-open Patent Publication No. H02-61025 (hereinafter, Patent Document 2), Japanese Unexamined Laid-open Patent Publication No. 2001-335872 (hereinafter, Patent Document 3)).

Moreover, as another production method of an aluminum substrate 2 low in thermal expansion coefficient, the following methods have been proposed: a method in which an Al—SiC composite low in thermal expansion coefficient is molded into a sheet shape in accordance with a powder metallurgy process; and a casting method in which Al—SiC composite powder is filled in a metal mold and Al molten metal or Al molten metal containing Si is injected under high pressure (see, Japanese Unexamined Laid-open Patent Publication No. 2004-128451 (hereinafter, Patent Document 4)).

Although it was tried to restrain occurrence of cracks by reducing the elasticity of resin used in the insulating layer, it failed to fully meet the reliability of the substrate.

However, in the rolled sheet as described in Patent documents 1, 2 and 3, since the Al—Si alloy was poor in workability, rolling it into a thin sheet causes cracked edges, which makes it difficult to manufacture a large-sized sheet required for a copper laminated board.

In the method as disclosed in Patent Document 4, it was difficult to manufacture a large-sized thin sheet, and it was poor in productivity and high in manufacturing cost. Furthermore, the substrate formed by the method was too hard to execute cutting processing, which is not suitable for a printed-circuit board.

The description herein of advantages and disadvantages of various features, embodiments, methods, and apparatus disclosed in other publications is in no way intended to limit the present invention. Indeed, certain features of the invention may be capable of overcoming certain disadvantages, while still retaining some or all of the features, embodiments, methods, and apparatus disclosed therein.

Other objects and advantages of the present invention will be apparent from the following preferred embodiments.

### DISCLOSURE OF INVENTION

The preferred embodiments of the present invention have been developed in view of the above-mentioned and/or other problems in the related art. The preferred embodiments of the present invention can significantly improve upon existing methods and/or apparatuses.

Among other potential advantages, some embodiments can provide a clad member low in thermal expansion coefficient and excellent in workability, which is suitable for use in a printed-circuit board.

Among other potential advantages, some embodiments can provide a production method of the clad member.

Among other potential advantages, some embodiments can provide a printed-circuit board using the clad member.

The aforementioned clad member has a structure as recited in the following Items [1] to [9].

[1] A clad member comprising a core member and skin members cladded on both sides of the core member,

wherein the core member is constituted by an aluminum alloy consisting of Si: 5 to 30 mass %, and the balance being aluminum and impurities, and

wherein the skin member is constituted by aluminum or an aluminum alloy consisting of Al: 98 mass % or above, and the balance being impurities.

[2] The clad member as recited in the aforementioned Item [1], wherein, in the aluminum alloy constituting the core member, Fe concentration is 1 mass % or less, and Ni concentration is 1 mass % or less.

[3] The clad member as recited in the aforementioned Item [1], wherein, in the aluminum alloy constituting the core member, Cu concentration is 0.5 mass % or less, Ti concentration is 0.3 mass % or less, Cr concentration is 0.3 mass % or less, P concentration is 0.1 mass % or less, and B concentration is 0.05 mass % or less.

[4] The clad member as recited in the aforementioned Item [1], wherein, in the aluminum alloy constituting the core member, Mn concentration is 0.2 mass % or less, Mg concentration is 0.2 mass % or less, and Zn concentration is 0.2 mass % or less.

[5] The clad member as recited in the aforementioned Item [1], wherein, in the aluminum or the aluminum alloy constituting the skin member, Si concentration is 1 mass % or less, Fe concentration is 1 mass % or less, Cu concentration is 0.5 mass % or less, and Mn concentration is 2 mass % or less.

[6] The clad member as recited in the aforementioned Item [5], wherein the Mn concentration is 0.002 to 1.2 mass %.

[7] The clad member as recited in the aforementioned Item [5], wherein, in the aluminum or the aluminum alloy constituting the skin member, Zn concentration is 0.5 mass % or less, and total concentration of elements other than Al and Zn is 0.3 mass % or less.

[8] The clad member as recited in the aforementioned Item [1], wherein a cladding rate of the skin members is 1 to 15% per one surface.

[9] The clad member as recited in the aforementioned Item [1], wherein a thickness of the clad member is 0.1 to 5 mm.

A production method of the clad member has a structure as recited in the following Item [10].

[10] A production method of a clad member, comprising the steps of:

disposing a plate made of aluminum or an aluminum alloy 98% or above in Al concentration, the balance being impurities on both surfaces of a plate made of an aluminum alloy consisting of Si: 5 to 30 mass %, the balance being Al and impurities; and

clad-rolling the plates to be pressure-bonded.

A printed-circuit board has a structure as recited in the following Items [11] to [13].

[11] A printed-circuit board, comprising:

an aluminum substrate made of a clad member comprising a core member and skin members cladded on both surfaces of the core material;

an insulating layer laminated on the aluminum substrate; and

a copper conducting layer laminated on the insulating layer,

wherein the core member of the clad member is made of an aluminum alloy containing Si: 5 to 30 mass %, the balance being Al and impurities, and

wherein the skin member made of aluminum or an aluminum alloy containing Al: 98 mass % or above, and the balance being impurities.

[12] The printed-circuit board as recited in the aforementioned Item [11], wherein the insulating layer contains insulating resin or an insulating resin composition in which a thermally conductive filler is blended in the insulating resin.

[13] The printed-circuit board as recited in the aforementioned Item [11], further comprising an anodic oxide film on a surface of the aluminum substrate.

The above and/or other aspects, features and/or advantages of various embodiments will be further appreciated in view of the following description in conjunction with the accompanying figures. Various embodiments can include and/or exclude different aspects, features and/or advantages where applicable. In addition, various embodiments can combine one or more aspect or feature of other embodiments where applicable. The descriptions of aspects, features and/or advantages of particular embodiments should not be construed as limiting other embodiments or the claims.

### BRIEF DESCRIPTION OF DRAWINGS

The preferred embodiments of the present invention are shown by way of example, and not limitation, in the accompanying figure, in which:

FIG. 1 is a cross-sectional view of a printed-circuit board according to an embodiment of the present invention; and

FIG. 2 is a cross-sectional view of the clad member according to an embodiment of the present invention.

### EFFECTS OF THE INVENTION

According to the invention as recited in the aforementioned Item [1], since the clad member is formed by cladding the skin members high in ductility on both surfaces of the core member, it is excellent in workability, and therefore it can be rolled into a thin plate while securing low thermal expansion coefficient as a cladding material by the core member. A good surface treatment nature can be obtained by the skin member.

According to the invention as recited in the aforementioned Item [2], the low thermal expansion coefficient of the clad member can be secured more assuredly.

According to the invention as recited in the aforementioned Item [3], the crystal grains of the core member can be formed into fine grains.

According to the invention as recited in the aforementioned Item [4], the excellent workability of the clad member can be secured more assuredly.

According to the invention as recited in the aforementioned Item [5], the excellent workability of the clad member can be secured more assuredly.

According to the invention as recited in the aforementioned Item [6], the excellent surface treatment nature of the clad member can be obtained.

According to the invention as recited in the aforementioned Item [7], the workability of the clad member can be secured more assuredly.

According to the invention as recited in the aforementioned Item [8], the excellent workability and the low thermal expansion coefficient of the clad member can be secured more assuredly.

The clad member according to the invention as recited in the aforementioned Item [9] is suitably used as a component material which may cause troubles due to the thermal expansion of, e.g., an aluminum substrate of a printed-circuit board.

With the production method of a clad member according to the invention as recited in the aforementioned Item [10], the clad member as recited in the aforementioned Item [1] can be manufactured.

In the printed-circuit board according to the invention as recited in the aforementioned Item [11], since the clad member as recited in the aforementioned Item [1] is used as an aluminum substrate, the difference of the thermal expansion coefficient between the aluminum substrate and the conducting layer is small, causing few warping even if heating and cooling are repeated. As a result, occurrence of cracks in the solder for bonding the electronic component can be restrained.

According to the invention as recited in the aforementioned Item [12], the bonding between the insulating layer and the aluminum substrate and the bonding between the insulating layer and the conducting layer are excellent.

According to the invention as recited in the aforementioned Item [13], the adhesion between the aluminum substrate and the insulating layer is excellent.

### BEST MODE FOR CARRYING OUT THE INVENTION

In the following paragraphs, some preferred embodiments of the invention will be described by way of example and not limitation. It should be understood based on this disclosure that various other modifications can be made by those in the art based on these illustrated embodiments.

FIG. 2 is a cross-sectional view showing a clad member 10 according to an embodiment of the present invention.

The clad member 10 includes a core member 11 made of an Al—Si alloy low in thermal expansion coefficient and independently low in workability, and skin members 12 and 12 higher in ductility than the core member 11 cladded on both surfaces of the core member 11. Thus, the clad member 10 is low in thermal expansion coefficient and excellent in workability.

In the present invention, the impurities in the aluminum alloy constituting the core member 11 denote elements other than Si and Al, and include elements added for the purpose of improving the characteristics of the core member 11, elements allowed to be contained within the range in which the characteristics of the core member 11 are not spoiled, and elements inevitably contained during the production steps. In the same manner, the impurities in the aluminum or the aluminum alloy constituting the skin member 12 denote elements other than Al, and include elements added for the purpose of improving the characteristics of the skin member 12, elements allowed to be contained within the range in which the characteristics of the skin member 12 are not spoiled, and elements inevitably contained during the production steps.

In the aluminum alloy constituting the core member 11, the significance of the Si inclusion and the reasons for limiting the Si concentration are as follows.

Si is an essential element necessary to lower the thermal expansion coefficient of the aluminum alloy. As shown in Table 1, the thermal expansion coefficient decreases as the Si concentration increases. In the present invention, an aluminum alloy 5 to 30 mass % in Si concentration is used. If the Si concentration is less than 5 mass %, an expected low thermal expansion coefficient cannot be attained. On the other hand, if it exceeds 30 mass %, the ductility deteriorates though the thermal expansion coefficient further decreases. If the ductility of the core member 11 deteriorates excessively, even if the skin members 12 are cladded on the core member 11, it becomes difficult to roll them into a thin plate. Furthermore, it also becomes difficult to execute processing, such as, e.g., machining, drilling, cutting, even after the clad rolling. Furthermore, higher Si concentration causes deterioration of the heat conductance, resulting in a member unsuitable for a member, such as, e.g., a printed-circuit board, which requires heat dissipation. Taking into consideration the thermal expansion coefficient and the easiness of the manufacturing or the post-processing, the preferable Si concentration is 15 to 27 mass %. As shown in Table 1, the thermal expansion coefficients of the aluminum alloy containing 15 to 27 mass % falls within the range of 19.6×10⁻⁶/K to 17.0×10⁻⁶/K, which is close to the Cu thermal expansion coefficient of 17.0×10⁻⁶/K. As a result, the use of the clad member 10 according to the present invention as a substrate of a printed-circuit board 1 can decrease the difference between the thermal expansion coefficient of the substrate 2 and that of the copper foil 4 as a conducting layer as small as possible.

TABLE 1
Thermal expansion coefficient and
Heat conductance of Al—Si alloy

| | Al—Si alloy | Thermal | |
|---|---|---|---|
| | Si content (mass %) | expansion | |
| | Balance: Al and impurities | coefficient | Heat conductance |
| Alloy | Si content | [×10⁻⁶/K] | [W/(m · K)] |
| A | 1 | 23.2 | 236.6 |
| B | 3 | 22.6 | 234.0 |
| C | 5 | 22.1 | 231.4 |
| D | 10 | 20.8 | 225.1 |
| E | 15 | 19.6 | 218.1 |
| F | 20 | 18.5 | 218.9 |
| G | 25 | 17.4 | 212.9 |
| H | 27 | 17.0 | 207.1 |
| I | 30 | 16.5 | 201.6 |
| J | 40 | 14.7 | 190.9 |

| | | |
|---|---|---|
| Cu | 17.0 | 397.0 |
| Pure Al | 23.5 | 238.0 |
| Si | 7.6 | 138.5 |

As the impurities in the aluminum alloy of the core member 11, Fe, Ni, Cu, Ti, Cr, P, B, Mn, Mg, and Zn can be exemplified.

Fe and Ni are elements having an effect of lowering the thermal expansion coefficient of an alloy if the content is slight. If the aluminum alloy contains a significant amount of these elements, however, the workability deteriorates, causing difficulty of the processing after clad rolling and/or rolling. Therefore, it is preferable that the Fe concentration is 1 mass % or less, and the Ni concentration is 1% or less. It is more preferable that the Fe concentration is 0.5 mass % or less and the Ni concentration is 0.5 mass % or less.

Cu and Cr are elements for enhancing mechanical properties. Ti and B are elements which makes the crystal grains in the alloy minute. P has an effect of making the Si grains into spherical and minute if the P concentration is 10 mass % or above. P can be added independently or as a compound of Cu and P. Among these elements, if a large amount of Cu is contained, the workability deteriorates, which makes it difficult to perform processing after clad rolling and rolling and also may cause deterioration of heat conductance. Therefore, it is preferable that the Cu concentration is 0.5 mass % or less. It is more preferable that the Cu concentration is 0.2 mass % or less. In the application in which heat dissipation nature is required like a printed-circuit board, the Cu concentration preferably falls within the aforementioned range to secure heat conductance. A large amount of Ti and Cr contained in the aluminum alloy causes deterioration of the workability, which may make it difficult to perform processing after clad rolling and rolling. Therefore, it is preferable that the Ti concentration is 0.3 mass % or less and the Cr concentration is 0.3 mass % or less. It is more preferable that the Ti concentration is 0.2 mass % or less and the Cr concentration is 0.2 mass % or less. Moreover, P concentration exceeding 0.1 mass % causes saturation of the aforementioned effects with respect to Si grains and less economical effect. Therefore, the P concentration is preferably 0.1 mass % or less. It is more preferable that the P concentration is 0.0001 to 0.1 mass % (1 to 1,000 mass ppm), more preferably 0.0003 to 0.01 mass % (3 to 100 mass ppm). Furthermore, a large amount of B may cause deteriorated machinability and cutting nature of the cladding material. Therefore, it is preferable that the B concentration is 0.05 mass % or less. It is especially preferable that the B concentration is 0.03 mass % or less.

A large amount of Mn, Mg, and/or Zn contained in the alloy may cause deterioration of the workability, which in turn may make it difficult to perform processing after clad rolling and rolling. Furthermore, Mn and Mg also have a possibility of deteriorating the heat conductance. Accordingly, it is preferable that the Mn concentration is 0.2 mass % or less and the Mg concentration is 0.2 mass % or less. It is more preferable that the Mn concentration is 0.1 mass % or less. It is more preferable that the Mg concentration is 0.1 mass %. As for Zn, there is a possibility of deteriorating the corrosion resistance, and therefore, it is preferable that the Zn concentration is 0.2 mass % or less. It is more preferable that the Zn concentration is 0.1 mass % or less.

The aforementioned impurities in the core member 11, i.e., Fe, Ni, Cu, Ti, Cr, P, B, Mn, Mg, and Zn each can be contained inevitably.

On the other hand, the skin member 12 itself has high ductility and secures the ductility as the clad member 10. In order to prevent or reduce occurrence of cracked edges at the time of clad rolling, it is necessary to use aluminum or an aluminum alloy 98 mass % or above in Al concentration. Al concentration of less than 98 mass % results in insufficient ductility, which may easily cause occurrence of cracked edges at the time of clad rolling. The preferable Al concentration of the skin member 12 is 99 mass % or above. Al concentration of 98 mass % or above is superior to an Al—Si alloy in surface treatment nature, and therefore cladding of the skin members 12 causes improved surface treatment nature superior to the core member 11.

As elements which may harm the ductility of the skin member 12, Si, Fe, Cu, and Mn can be exemplified. It is preferable that the Si concentration is 1 mass % or less, the Fe concentration is 1 masse or less, the Cu concentration is 0.5 mass % or less, and the Mn concentration is 2 mass % or less. It is more preferable that the Si concentration is 0.6 mass % or less, the Fe concentration is 0.7 mass % or less, the Cu concentration is 0.2 mass % or less, and the Mn concentration is 1.2 mass % or less.

In addition to the above, as elements which may harm the ductility of the skin member 12, Zn can be exemplified. The Zn concentration is preferably 0.5 mass % or less. Another impurities other than Al and Zn, e.g., Cr, Ti, etc., it is preferable that they are 0.3 mass % or less in total. The especially preferable Zn concentration is 0.1 mass % or less, and the especially preferable elements other than Al and Zn are 0.15 mass % or less in total.

Among the aforementioned elements, Mn has an effect of enhancing anti-crack nature (hard-to-be-cracked) after rolling without sacrificing the surface treatment nature of the clad member 10, such as, e.g., anodization processing or conversion treatment. Although it is preferable that the Mn content is smaller to secure the ductility, the aforementioned effect can be attained even if Mn is contained within the range in which clad rolling is not harmed, more specifically within the range in which the Mn concentration falls within the range of 0.002 to 1.2 mass %. Only taking into consideration the ductility of the skin member 12, it is preferable that the Mn concentration is 0.05 mass % or less. In cases where priority is given to a surface anti-crack nature, the preferable Mn concentration is 0.3 to 1.2 mass %.

In the clad member according to the present invention, the cladding rate of the skin member is given by: cladding rate (%)=(thickness of skin member/thickness of clad member)×100. Although the cladding rate is not limited, it is preferable that the cladding rate is 1 to 15% at one side. If the cladding rate is less than 1%, the workability as a clad member 10 is insufficient and an effect of preventing the occurrence of cracked edges at the time of clad rolling is poor. On the other hand, if the cladding rate is 15%, the workability can fully be enhanced, and therefore there is no merit to set the cladding rate so as to exceed 15%. Moreover, the skin member 12 is larger than the core member in thermal expansion coefficient, and therefore, if the cladding rate exceeds 15%, the thermal expansion coefficient as a clad member will also increase. It is more preferable that the cladding rate is 5 to 10% per one side.

Although the thickness of the clad member 10 is not limited, it can be formed into a thin plate with a thickness of 0.1 to 5 mm because of the improved workability due to the cladded skin members. The thin plate with the aforementioned thickness can be widely used for various applications, such as, e.g., an aluminum substrate for a printed-circuit board, a thermal-shock absorbing member for a power device, such as, e.g., an IGBT (insulated gate type bipolar transistor), a structural element, such as, e.g., a casing or a chassis for mounting various heat generating electronic components, or another parts or components required to lessen problems due to thermal expansion. In the case of using the clad member 10 as the substrate 2, it is especially preferable that the thickness is 0.5 to 4 mm.

Furthermore, the surface treatment nature is enhanced by the skin member than the core member, and therefore it is excellent in adhesiveness with respect to anodic oxidation coatings and/or conversion coatings. For this reason, in the aforementioned applications, a surface treatment also can be performed if needed.

The production method of the clad member according to the present invention is not limited. The clad member 10 can be manufactured by, e.g., the same method as a method for well-known clad members. For example, a raw plate for core members and a raw plate for skin members each having predetermined compositions are manufactured by any known method, such as, e.g., casting, rolling, and/or extrusion, and then these plates are subjected to clad rolling to be bonded with each other, and then rolled into a predetermined thickness if necessary. In this case, since it is manufactured by rolling, a large-sized clad member can be manufactured. The clad member 10 also can be manufactured by press-bonding core member material and skin member material by clad extrusion, or by fusion-bonding a sheet-like skin member manufactured separately to a core member while casting the core member by clad casting and rolling into a predetermined thickness if necessary.

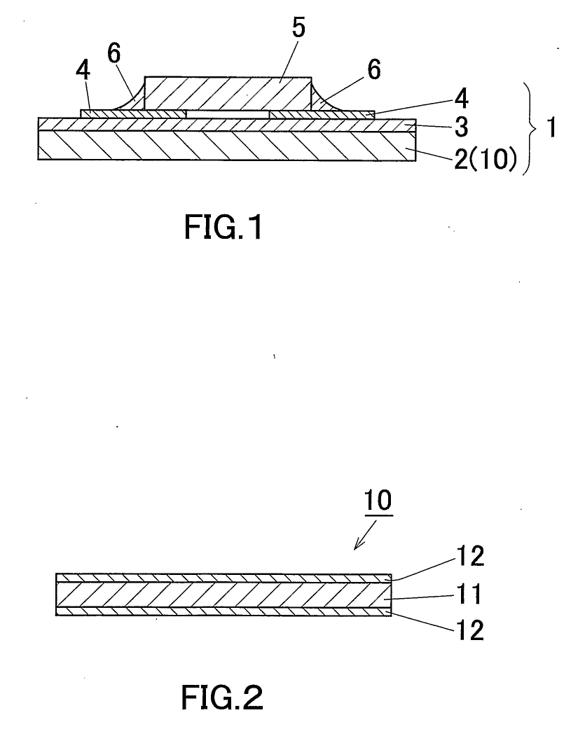

As shown in FIG. 1, the printed-circuit board 1 according to the present invention includes a substrate 10 which is the aforementioned clad member, an insulating layer 3 laminated on this aluminum substrate 10, a copper foil as the conducting layer 4 of a prescribed circuit shape laminated on the insulating layer 3. In this printed-circuit board 1, since the thermal expansion coefficient of the aluminum substrate 10 is low, the difference between the thermal expansion coefficient of the aluminum substrate 10 and that of the conducting layer 4 is small. Therefore, even if heating and cooling are repeated by the heat generated from the electronic component 5 attached on the conducting layer 4, there are few warping, which in turn restrains occurrence of cracks in the solder 6.

The insulating layer 3 can be made of insulating material capable of directly or indirectly bonding to the clad member 10. Specifically, as the insulating material, insulating resin or an insulating resin composite in which a thermally conductive filler is blended in the insulating resin can be exemplified. Such a resin base insulating layer is good in bondability with respect to the aluminum substrate 2 and the conducting layer 3, and is not easily broken as compared with ceramics, and makes it possible to manufacture a large-sized substrate. It should be noted that in the present invention, the material of the insulating layer 3 is not limited to the aforementioned insulating resin or the aforementioned insulating resin composite, and can be, e.g., ceramics. In the case of ceramics, it can be bonded to the clad member 10 with adhesive.

The insulating resin is preferably excellent in heat resistance, small in thermal expansion coefficient, capable of adhering to the clad member 10, and excellent in adhesion. As such resin which fulfills these conditions, epoxy resin or polyimide resin can be exemplified. The epoxy resin can be recommended in that it is excellent in adhesion especially with a copper foil, low in hygroscopicity, low in cost. The polyimide resin can be recommended in that the chemical resistance is excellent, the thermal expansion coefficient in the thickness direction is small, and deformation can be restrained.

Furthermore, by using an insulating resin composite in which a thermally conductive filler is blended in the insulating resin, the heat conductance of the insulating layer can be enhanced, which in turn can enhance radiation performance. It is preferable that the thermally conductive filler is an insulator high in heat conductance and is made of metal oxide or metal nitride. Concretely, SiO₂, Al₂O₃, BeO, MgO, Si₃N₄, BN, and AlN can be exemplified. These thermally conductive fillers can be used independently, or can be used in any combination thereof. The thermally conductive filler increases in heat conductance of the insulating layer 3 as the concentration in the resin composite increases. The preferable concentration is 40 to 90 capacity %. If it is less than 40 capacity %, the improvement effect of the heat conductance is poor. On the other hand, if it exceeds 90 capacity %, the adhesion with a flat tube deteriorates, causing deterioration of radiation performance. It is more preferable that the concentration is 60 to 80 capacity %. The thermally conductive filler preferably has a particle diameter of 10 to 40 μm.

In each of the insulating layers 3 of the aforementioned two types, the thickness is preferably 0.01 to 0.5 mm.

The joining of the aforementioned clad member 10, the insulating layer 3, and the conducting layer 4 can be performed by any known method, such as, e.g., hot press.

For example, in cases where thermosetting resin is used as the insulating resin for the insulating layer 3, the following method can be exemplified. That is, a conducting layer 4, an insulating layer 3, and a clad member 10 are superimposed. Then, the upper and lower sides thereof are pinched by stainless steel plates and press-heated via cushion members. This hot press causes hardening of the insulating layer 3 and joining of the insulating layer 3 to the clad member 10 and the conducting layer 4, resulting in an integration thereof. In cases where the conducting layer 4 is joined to a part of the insulating layer 3, the joining is performed using a positioning sheet and a backing plate. That is, a conducting layer 4 is bonded on the positioning sheet and disposed on the insulating layer 3 via the backing plate with pores corresponding to the conducting layer 4, and then disposed on the clad member 10. Then, these are pinched by stainless steel plates and press-heated via cushion materials. Thus, the conducting layer 4 is joined to the predetermined position of the insulating layer 3. As the copper used for the conducting layer, a copper plate, a copper foil, and a copper-coating layer, can be exemplified.

In order to increase the adhesive strength between the clad member 10 and the insulating layer 3, it is also preferable to form an anodic oxidation coating on the surface of the clad member 10. In this case, insulating resin enters in the pores of the anodic oxidation coating, resulting in high adhesive strength due to the anchor effects. The type of the coating is not limited, and a coating caused by phosphate treatment or sulfuric acid treatment can be exemplified. The clad member according to the present invention is enhanced in surface treatment nature by the skin member, and therefore it is excellent in adhesion with respect to anodic oxidation coatings.

### EXAMPLES

The balance compositions of the alloys B to J among Al—Si alloys shown in Table 1 is shown in Table 2. Clad members shown in Table 4 as Examples 1 to 23 and shown in Table 5 as Comparative Examples 1 to 7 were manufactured using the Al—Si alloys B to J as core member materials and the compositions shown in Table 3 as skin member materials.

As for the core member material, an ingot is manufactured by the book mold method, and the ingot is subjected to a soaking treatment for holding it at 490±10° C. for 10 hours and then air-cooled. Furthermore, it is formed into a thickness of 15 mm by executing face cutting to thereby obtain a core member raw plate. As to the skin member material, a raw plate for skin members is manufactured by press-rolling an ingot. As to the thickness of the raw plate for skin members, three types of raw plates different in thickness, i.e., 2 mm (10.5% of cladding rate), 1.5 mm (8.3% of cladding rate), and 0.5 mm (3.1% of cladding rate), were prepared.

Then, the raw plates for skin members were disposed on both surfaces of the raw plate for core members, heated at 500° C. for 2 hours, then rolled at the rolling reduction of about 2 to 10% until it became 9 mm in thickness, and further rolled at the rolling reduction of about 10 to 20% until it became 3 mm in thickness. Furthermore, it was cold-rolled until it became 1 mm in thickness to thereby manufactured a clad member 10 as shown in FIG. 2. The alloy symbols of the core member and the skin member are shown together with the cladding rate of one side in Tables 4 and 5.

In Comparative Examples Nos. 8 to 12, the core member was rolled into a thickness of 1 mm independently.

The thermal expansion coefficient and the heat conductance of each clad member were measured and compared with the independent core member. The thermal expansion coefficient and the thermal conductivity of the independent core member shown in Tables 4 and 5 were quoted from Table 1.

The workability and the surface treatment nature of each clad member were tested and evaluated by the following method. The evaluation results are collectively shown in Tables 4 and 5.

### (Workability)

It was Evaluated Based on the Following Standard Depending on the length (cracked edge length from a side end) of the cracked edge generated at the side edge of the width direction of the cladding material at the time of clad rolling.

⊚: 2 mm or less

◯: 2 mm or above, but less than 4 mm

Δ: 4 mm or above, but less than 7 mm

X: 7 mm or above

### (Surface Treatment Nature—Anodization Processing)

The clad member was subjected to anodization processing in a sulfate bath at a current density of 1.5 A/dm² at 20° C., 15 V/V %, to thereby form a film of 1 μm thickness. Then, the formed anodic oxidation coating was zoomed by 100 times with an optical microscope, and the number of pits within the view of 10 mm square was counted. It can be estimated that the fewer the pits are the surface treatment nature is superior.

⊚: 3 pits or less

◯: 4 to 10 pits

X: 11 pits or more

TABLE 2
Core member composition

| | Core member composition (mass %) balance: Al | | | | | | | | | | |
|---|---|---|---|---|---|---|---|---|---|---|---|
| Alloy | Si | Fe | Ni | Cu | Ti | Cr | P | B | Mn | Mg | Zn |
| B: Comparative composition | 3 | 0.1 | 0.01 | 0.2 | 0.01 | 0.01 | 0.005 | 0.01 | 0.01 | 0.01 | 0.01 |
| C: Inventive composition | 5 | 0.1 | 0.01 | 0.2 | 0.01 | 0.01 | 0.005 | 0.01 | 0.01 | 0.01 | 0.01 |
| D: Inventive composition | 10 | 0.1 | 0.01 | 0.2 | 0.01 | 0.01 | 0.005 | 0.01 | 0.01 | 0.01 | 0.01 |
| E: Inventive composition | 15 | 0.1 | 0.01 | 0.2 | 0.01 | 0.01 | 0.005 | 0.01 | 0.01 | 0.01 | 0.01 |
| F: Inventive composition | 20 | 0.1 | 0.01 | 0.2 | 0.01 | 0.01 | 0.005 | 0.01 | 0.01 | 0.01 | 0.01 |
| G: Inventive composition | 25 | 0.1 | 0.01 | 0.2 | 0.01 | 0.01 | 0.005 | 0.01 | 0.01 | 0.01 | 0.01 |
| H: Inventive composition | 27 | 0.2 | 0.01 | 0.2 | 0.01 | 0.01 | 0.005 | 0.01 | 0.01 | 0.01 | 0.01 |
| I: Inventive composition | 30 | 0.2 | 0.01 | 0.3 | 0.01 | 0.01 | 0.005 | 0.01 | 0.01 | 0.01 | 0.01 |
| J: Comparative composition | 40 | 0.1 | 0.01 | 0.2 | 0.01 | 0.01 | 0.005 | 0.01 | 0.01 | 0.01 | 0.01 |

TABLE 3
Skin member

| | Skin member composition (mass %) balance: Al | | | | | | |
|---|---|---|---|---|---|---|---|
| Skin member | Al | Si | Fe | Cu | Mn | Zn | etc. |
| a: Inventive composition | 99.1 | 0.12 | 0.44 | 0.02 | 0.01 | 0.01 | 0.3 |
| b: Inventive composition | 99.6 | 0.08 | 0.23 | 0.01 | 0.01 | 0.01 or less | 0.05 |
| c: Inventive composition | 98.45 | 0.2 | 0.2 | 0.05 | 1.0 | 0.05 | 0.05 |
| d: Comparative composition | 97.5 | 0.8 | 0.8 | 0.5 | 0.1 | 0.2 | 0.1 |

TABLE 4
Clad member (Example)

| | | | | Clad rate of | | | | | | |
|---|---|---|---|---|---|---|---|---|---|---|
| | | Core | Skin | skin | Thermal expansion coefficient | | Heat conductance | | | Surface |
| | | member | member | member | [×10⁻⁶/K] | | [W/(m · K)] | | | treatment |
| | | ( ): Si amount | Note 1) | (%) | Core member | Clad member | Core member | Clad member | Workability | nature |
| Example | 1 | C (5) | b | 10.5 | 22.1 | 22.4 | 231.4 | 229.0 | ⊚ | ⊚ |
| | 2 | D (10) | b | 10.5 | 20.8 | 21.4 | 225.1 | 224.0 | ⊚ | ⊚ |
| | 3 | E (15) | b | 10.5 | 19.6 | 20.4 | 218.1 | 218.5 | ⊚ | ⊚ |
| | 4 | F (20) | b | 10.5 | 18.5 | 19.6 | 218.9 | 219.1 | ⊚ | ⊚ |
| | 5 | G (25) | b | 10.5 | 17.4 | 18.7 | 212.9 | 214.4 | ⊚ | ⊚ |
| | 6 | H (27) | b | 10.5 | 17.0 | 18.4 | 207.1 | 209.8 | ⊚ | ⊚ |
| | 7 | I (30) | b | 10.5 | 16.5 | 18.0 | 201.6 | 205.5 | ⊚ | ⊚ |
| | 8 | E (15) | a | 10.5 | 19.6 | 20.5 | 218.1 | 220.6 | ⊚ | ◯ |
| | 9 | F (20) | a | 10.5 | 18.5 | 19.7 | 218.9 | 221.2 | ⊚ | ◯ |
| | 10 | G (25) | a | 10.5 | 17.4 | 18.8 | 212.9 | 216.5 | ⊚ | ◯ |
| | 11 | H (27) | a | 10.5 | 17.0 | 18.5 | 207.1 | 211.9 | ⊚ | ◯ |
| | 12 | E (15) | c | 10.5 | 19.6 | 20.4 | 218.1 | 212.2 | ◯ | ◯ |
| | 13 | F (20) | c | 10.5 | 18.5 | 19.5 | 218.9 | 212.8 | ◯ | ◯ |
| | 14 | G (25) | c | 10.5 | 17.4 | 18.6 | 212.9 | 208.1 | ◯ | ◯ |
| | 15 | H (27) | c | 10.5 | 17.0 | 18.3 | 207.1 | 203.5 | ◯ | ◯ |
| | 16 | E (15) | b | 8.3 | 19.6 | 20.3 | 218.1 | 218.4 | ⊚ | ⊚ |
| | 17 | F (20) | b | 8.3 | 18.5 | 19.3 | 218.9 | 219.1 | ⊚ | ⊚ |
| | 18 | G (25) | b | 8.3 | 17.4 | 18.4 | 212.9 | 214.1 | ⊚ | ⊚ |
| | 19 | H (27) | b | 8.3 | 17.0 | 18.1 | 207.1 | 209.2 | ⊚ | ⊚ |
| | 20 | E (15) | b | 3.1 | 19.6 | 19.8 | 218.1 | 218.2 | ⊚ | ⊚ |
| | 21 | F (20) | b | 3.1 | 18.5 | 18.8 | 218.9 | 219.0 | ⊚ | ⊚ |
| | 22 | G (25) | b | 3.1 | 17.4 | 17.8 | 212.9 | 213.3 | ⊚ | ⊚ |
| | 23 | H (27) | b | 3.1 | 17.0 | 17.4 | 207.1 | 207.9 | ⊚ | ⊚ |

Note 1)
a: Al concentration 98 mass % or above,
b: Al concentration 99 mass % or above,
c: Mn is added

TABLE 5
Clad member (Comparative example)

| | | | | | Thermal expansion | | | | | |
|---|---|---|---|---|---|---|---|---|---|---|
| | | | | | coefficient | | Heat conductance | | | |
| | | Core | Skin | | [×10⁻⁶/K] | | [W/(m · K)] | | | Surface |
| | | member | member | Cladding rate of skin | Core | Clad | Core | Clad | | treatment |
| | | ( ): Si content | Note 1) | member (%) | member | member | member | member | Workability | nature |
| Comparative | 1 | B (3) | b | 10.5 | 22.6 | 22.8 | 234.0 | 231.1 | ⊚ | ◯ |
| Example | 2 | J (40) | b | 10.5 | 14.7 | 16.6 | 190.9 | 197.0 | X | ◯ |
| | 3 | E (15) | d | 10.5 | 19.6 | 20.4 | 218.1 | 214.3 | Δ | ◯ |
| | 4 | F (20) | d | 10.5 | 18.5 | 19.5 | 218.9 | 214.9 | Δ | ◯ |
| | 5 | G (25) | d | 10.5 | 17.4 | 18.7 | 212.9 | 210.2 | Δ | ◯ |
| | 6 | H (27) | d | 10.5 | 17.0 | 18.3 | 207.1 | 205.6 | Δ | ◯ |
| | 7 | I (30) | d | 10.5 | 16.5 | 17.9 | 201.6 | 201.3 | Δ | ◯ |

| | | | | | |
|---|---|---|---|---|---|
| 8 | E (15) independently rolled into 1 mm plate | 19.6 | 218.1 | X | X |
| 9 | F (20) independently rolled into 1 mm plate | 18.5 | 218.9 | X | X |
| 10 | G (25) independently rolled into 1 mm plate | 17.4 | 212.9 | X | X |
| 11 | H (27) independently rolled into 1 mm plate | 17.0 | 207.1 | X | X |
| 12 | I (30) independently rolled into 1 mm plate | 16.5 | 201.6 | X | X |

Note 1)
a: Al concentration 98 mass % or above,
b: Al concentration 99 mass % or above,
c: Mn is added,
d: Al concentration less than 98 mass %

From the results shown in Table 4, it can be understood that the clad member of each Example is superior to an independent core member in workability and can be manufactured into a thin plate. Furthermore, the low thermal expansion coefficient of the core member is maintained mostly, and therefore it is an aluminum plate of low thermal expansion. Moreover, the heat conductance was also high by the regulated impurity amount in the core member. As compared with Comparative Examples Nos. 8 to 12, the surface treatment nature was enhanced than the independent core member due to the cladding of the skin members.

On the other hand, since Comparative Example 1 was high in thermal expansion coefficient of the core member, it cannot be served as a clad member low in thermal expansion. Since Comparative Example 2 was excessive in Si amount in the core member, the workability was insufficient even if skin members were cladded. As shown in Comparative Examples 8 to 12, even if the same core member was used, cracked edges were generated at the time of rolling it into a thin plate. Moreover, as shown in Comparative Examples 3 to 7, even if aluminum less than 98 mass % in Al concentration was used as a skin member, the workability as a clad member was insufficient, and a good clad member could not be manufactured.

### INDUSTRIAL APPLICABILITY

The clad member according to the present invention is low in thermal expansion and excellent in workability. Therefore, a thin plate can be formed. The clad member can be widely used as component material, such as, e.g., an aluminum substrate for a printed-circuit board, which causes problems due to thermal expansion.

While the present invention may be embodied in many different forms, a number of illustrative embodiments are described herein with the understanding that the present disclosure is to be considered as providing examples of the principles of the invention and such examples are not intended to limit the invention to preferred embodiments described herein and/or illustrated herein.

While illustrative embodiments of the invention have been described herein, the present invention is not limited to the various preferred embodiments described herein, but includes any and all embodiments having equivalent elements, modifications, omissions, combinations (e.g., of aspects across various embodiments), adaptations and/or alterations as would be appreciated by those in the art based on the present disclosure. The limitations in the claims are to be interpreted broadly based on the language employed in the claims and not limited to examples described in the present specification or during the prosecution of the application, which examples are to be construed as non-exclusive. For example, in the present disclosure, the term “preferably” is non-exclusive and means “preferably, but not limited to.” In this disclosure and during the prosecution of this application, means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure are not recited. In this disclosure and during the prosecution of this application, the terminology “present invention” or “invention” may be used as a reference to one or more aspect within the present disclosure. The language present invention or invention should not be improperly interpreted as an identification of criticality, should not be improperly interpreted as applying across all aspects or embodiments (i.e., it should be understood that the present invention has a number of aspects and embodiments), and should not be improperly interpreted as limiting the scope of the application or claims. In this disclosure and during the prosecution of this application, the terminology “embodiment” can be used to describe any aspect, feature, process or step, any combination thereof, and/or any portion thereof, etc. In some examples, various embodiments may include overlapping features. In this disclosure and during the prosecution of this case, the following abbreviated terminology may be employed: “e.g.” which means “for example;” and “NB” which means “note well.”

1. A clad member comprising a core member and skin members cladded on both sides of the core member,
wherein the core member is constituted by an aluminum alloy consisting of Si: 5 to 30 mass %, and the balance being aluminum and impurities, and
wherein the skin member is constituted by aluminum or an aluminum alloy consisting of Al: 98 mass % or above, and the balance being impurities.

2. The clad member as recited in claim 1, wherein, in the aluminum alloy constituting the core member, Fe concentration is 1 mass % or less, and Ni concentration is 1 mass % or less.

3. The clad member as recited in claim 1, wherein, in the aluminum alloy constituting the core member, Cu concentration is 0.5 mass % or less, Ti concentration is 0.3 mass % or less, Cr concentration is 0.3 mass % or less, P concentration is 0.1 mass % or less, and B concentration is 0.05 mass % or less.

4. The clad member as recited in claim 1, wherein, in the aluminum alloy constituting the core member, Mn concentration is 0.2 mass % or less, Mg concentration is 0.2 mass % or less, and Zn concentration is 0.2 mass % or less.

5. The clad member as recited in claim 1, wherein, in the aluminum or the aluminum alloy constituting the skin member, Si concentration is 1 mass % or less, Fe concentration is 1 mass % or less, Cu concentration is 0.5 mass % or less, and Mn concentration is 2 mass % or less.

6. The clad member as recited in claim 5, wherein the Mn concentration is 0.002 to 1.2 mass %.

7. The clad member as recited in claim 5, wherein, in the aluminum or the aluminum alloy constituting the skin member, Zn concentration is 0.5 mass % or less, and total concentration of elements other than Al and Zn is 0.3 mass % or less.

8. The clad member as recited in claim 1, wherein a cladding rate of the skin members is 1 to 15% per one surface.

9. The clad member as recited in claim 1, wherein a thickness of the clad member is 0.1 to 5 mm.

10. A production method of a clad member, comprising the steps of:
disposing a plate made of aluminum or an aluminum alloy 98% or above in Al concentration, the balance being impurities on both surfaces of a plate made of an aluminum alloy consisting of Si: to 30 mass %, the balance being Al and impurities; and
clad-rolling the plates to be pressure-bonded.

11. A printed-circuit board, comprising:
an aluminum substrate made of a clad member comprising a core member and skin members cladded on both surfaces of the core material;
an insulating layer laminated on the aluminum substrate; and
a copper conducting layer laminated on the insulating layer, wherein the core member of the clad member is made of an aluminum
alloy containing Si: 5 to 30 mass %, the balance being Al and impurities, and
wherein the skin member made of aluminum or an aluminum alloy containing Al: 98 mass % or above, and the balance being impurities.

12. The printed-circuit board as recited in claim 11, wherein the insulating layer contains insulating resin or an insulating resin composition in which a thermally conductive filler is blended in the insulating resin.

13. The printed-circuit board as recited in claim 11, further comprising an anodic oxide film on a surface of the aluminum substrate.
